(19) United States
(12) Patent Application Publication
(10) Pub. No.: US 2025/0380366 A1
(43) Pub. Date: Dec. 11, 2025

(54) PROTECTIVE ENCLOSURE FOR ELECTRONIC CIRCUITS

(71) Applicant: Inventus Holdings, LLC, Juno Beach, FL (US)

(72) Inventors: Kelsa B ANDERSON, Juno Beach, FL (US); Rick D. DEGELAU, Juno Beach, FL (US); Nicholas A WAYNE, Juno Beach, FL (US); Michael T. Orendorff, Verona, WI (US)

(21) Appl. No.: 18/734,136

(22) Filed: Jun. 5, 2024

(51) Int. Cl. H05K 5/00; H05K 5/02; H05K 7/20; H05K 13/04

(52) U.S. Cl. CPC H05K 5/0073; H05K 13/0486; H05K 5/0091; H05K 5/0247; H05K 7/20909

(57) ABSTRACT

Devices and methods for protecting an electronic circuit. A device includes a base frame, an electronic circuit, and a cage frame depending from the base frame. The cage frame is configured to provide physical protection on at least four sides for the electronic circuit. The cage frame also defines a plurality of openings configured to provide air circulation across the electronic circuit. The device also has at least one fan disposed within the cage frame and configured to at least partially drive the air circulation. A method involves providing the above components. These devices and methods are able to be further adapted to provide for the retrofit of an installed electronics device.

### FIELD OF THE DISCLOSURE

The present disclosure generally relates to enclosures for electronics, and more particularly to protective enclosures that provide physical protection for circuit components and cooling apparatuses.

### BACKGROUND

Several applications using electronic circuits incorporate large and somewhat physically delicate components such as capacitors, heat sinks, other elements, or combinations of these. In an example of electrical power devices, such as three-phase electrical power conversion equipment, such devices include large electrolytic capacitors and cooling components that require a significant amount of volume and are in some ways physically delicate and prone to damage by forceful contact with other objects. Devices incorporating these large and delicate components are sometimes installed in other enclosures, such as equipment cabinets. Due to the large volume occupied by these large and delicate components and the intent to mount them in other enclosures sometimes results in those components being mounted on a device without significant physical protection for those components. In an example of electrical power devices, these devices may be at least partially mounted in other enclosures but those enclosures often have limited physical space. The limited physical space in such enclosures can subject the delicate components to physical impact or other damaging contact at time such as during servicing, installation and removal, other activities in the cabinet, or combinations of these. The likelihood of damage in some cases is increased due to the several large gauge, very rigid electrical cables that are connected to electrical power devices that greatly restrict movement of the device for installation and removal.

### BRIEF DESCRIPTION OF THE DRAWINGS

The accompanying figures where like reference numerals refer to identical or functionally similar elements throughout the separate views, and which together with the detailed description below are incorporated in and form part of the specification, serve to further illustrate various embodiments and to explain various principles and advantages all in accordance with the present disclosure, in which:

FIG. 1 depicts a view of a power electronic device within a protective cooling enclosure, according to an example;

FIG. 2 depicts an electronic circuit detailed view of the power electronic device within a protective cooling enclosure depicted in FIG. 1, according to an example;

FIG. 3 depicts a wind turbine with an electronic circuit including the power electronic device depicted in FIG. 1, according to an example.;

FIG. 4 depicts a power electrical device installation including a power electronic device within a protective cooling enclosure as depicted in FIG. 1, according to an example; and

FIG. 5 depicts a method of providing protection and cooling of an electronic circuit, according to an example.

### DETAILED DESCRIPTION

As required, detailed embodiments are disclosed herein; however, it is to be understood that the disclosed embodiments are merely examples and that the devices and methods described below can be embodied in various forms. Therefore, specific structural and functional details disclosed herein are not to be interpreted as limiting, but merely as a basis for the claims and as a representative basis for teaching one skilled in the art to variously employ the disclosed subject matter in virtually any appropriately detailed structure and function. Further, the terms and phrases used herein are not intended to be limiting, but rather, to provide an understandable description.

The terms “a” or “an”, as used herein, are defined as one or more than one. The term plurality, as used herein, is defined as two or more than two. The term another, as used herein, is defined as at least a second or more. The terms “including” and “having,” as used herein, are defined as comprising (i.e., open language). The term “coupled,” as used herein, is defined as “connected,” although not necessarily directly, and not necessarily mechanically. The term "configured to" describes hardware, software or a combination of hardware and software that is adapted to, set up, arranged, built, composed, constructed, designed or that has any combination of these characteristics to carry out a given function. The term "adapted to" describes hardware, software or a combination of hardware and software that is capable of, able to accommodate, to make, or that is suitable to carry out a given function.

The below described example devices and methods provide electronic enclosures that provide physical protection for physically delicate component attached to the device where they could be damaged without such physical protection. These devices and methods further provide cooling components for elements within the enclosure where those cooling components are also protected by the enclosure.

These devices in some examples are connected to a number of thick gauge cables that exchange electrical power with the device. These cables in some examples are attached to connection lugs that are attached to circuit boards or other structures of the device. In some examples, manipulation of the device during installation or removal can cause these lugs to break away from their attachment points and require potentially costly and lengthy repairs or replacements. In some examples, such cables are relatively short and restrict the movement of the device when the cable are connected, such as when being installed or removed from a cabinet. This restricted movement increases the likelihood that part of the device will strike another nearby object. In an example with conventional devices that do not have protection for exposed components such as capacitors and fans, such a strike may cause damage to these components, their mounting structures, other components, or combinations of these, thus requiring potentially costly or lengthy repairs.

In some examples, the below described devices and methods are able to be adapted to provide for the retrofit of an installed existing electronic device. In some examples, installed electronic devices include delicate components that are not sufficiently protected. The insufficiently protected delicate components of these devices are able to be damaged in the course of working on these devices. Such damage to these delicate components is able to occur by impact or other forces applied to those components during work on the installed electronic devices either while it is installed in a cabinet, during removal of the electronic device from its installation location, during reinstallation of the electronic device into its installation location, or combinations of these.

Retrofit of such installed electronic devices may occur due to any one or more reasons, such as to make improvements of any nature to the design of the electronic device. An example of such a retrofit includes replacing an existing Alternating Current-to-Alternating Current (AC-to-AC) electric power conversion device that is installed in a cabinet or other structure with a retrofitting device that includes a compatible circuit capable of replacing the existing installed AC-to-AC electric power conversion device. Using the below described retrofitting techniques improves the overall operations and reliability of systems that include an electronic device, such as an AC-to-AC electric power conversion device, with a suitable replacement that provides better physical protection and improved cooling for the delicate components of that device.

An example of an existing installed AC-to-AC electric power conversion device is a three-phase full-bridge power converter that is part of a voltage source power converter unit used on a Doubly Fed Induction Generator (DFIG) wind turbine. That device in an example is able to handle at least 1.5 Megawatt (MW) of electrical power and interfaces the electrical output of rotor of the generator to the grid; through rotor frequency matching and by acting as a bi-directional power source. In an example, two such devices are used for each wind turbine where one device converts the AC rotor output power to DC power and another to convert that DC power to AC for delivery to the grid. In some examples, the existing installed device used in installed systems was not intended for the application of installation in or near a wind turbine, and the mechanical construction of the existing installed device does not provide sufficient physical protection for several delicate components that are mounted in unprotected locations on the device. Manipulation of this device into the restricted confines of cabinets near or in wind turbines increases the likelihood that such delicate components will suffer impacts by other objects when the device is being installed or removed such as for service. The incorporation of the below described devices and method in providing an AC-to-AC power converter device that processes such high electrical power levels, e.g., at least 1 Megawatt (MW), advantageously improvise the reliability and serviceability of such devices.

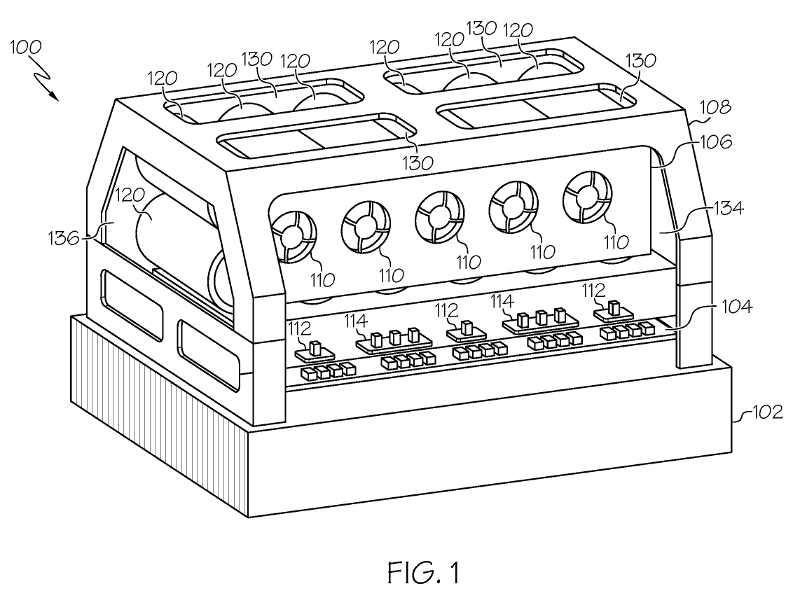

FIG. 1 depicts a power electronic device within a protective cooling enclosure 100, according to an example. The power electronic device within a protective cooling enclosure 100 depicts an example of a protective enclosure that includes a base frame 102 and a cage frame 108 that form a protective structure configured to physically protect components enclosed inside a cavity formed by the base frame 102 and the cage frame 108. The cage frame 108 in this example provides protection on at least four sides of an electronic circuit board 104 and also defines a number of openings, including top openings 130, long side openings 134 and short side openings 136, that facilitate air circulation through the protective structure to adequately cool components therein.

In an example, the power electronic device within a protective cooling enclosure 100 is a device that is configured as a retrofitting replacement for an existing electronic device. In other words, the power electronic device within a protective cooling enclosure 100 is designed to be retrofitted into an existing system, such as an existing wind turbine installation. The existing system in an example includes an existing Alternating Current-to-Alternating Current (AC-to-AC) conversion device that operates as is described above. The existing AC-to-AC conversion device in an example has less physical protection for some of its delicate components. Retrofitting the existing AC-to-AC conversion device with the power electronic device within a protective cooling enclosure 100 provides many benefits such as one or more of increased reliability due to better physical protection for delicate components, an improved circuit design that uses newer components or that have other features, improved monitoring equipment included in the device, other benefits, or combinations of these.

In an example, the base frame 102 is configured to be mounted on an existing physical interface for the existing electronic device. For example, in an instance of the existing AC-to-AC conversion device being mounted into an opening of a cabinet, the base frame 102 can have physical dimensions and features compatible with the physical mounting and attachment of the base frame 102 to the opening in the cabinet where the existing AC-to-AC conversion device was mounted. Further, the cage frame in an example has physical dimensions that are compatible with installation of the power electronic device with a protective cooling enclosure 100 into that same opening.

The electronic circuits within a protective cooling enclosure 100 in the illustrated example contains an electronic circuit board 104. In an example, the electronic circuit implements an electric power conversion module such as is used to process electrical power produced by a wind turbine in order to provide the electrical power to a consumer. In an example, this electronic circuit board 104 is a compatible circuit suitable to replace an Alternating Current-to-Alternating Current conversion circuit within an installed Alternating Current-to-Alternating Current conversion device.

The power electronic device within a protective cooling enclosure 100 depicts three (3) AC power connectors 112 and two (2) DC power connectors 114. The three (3) AC power connectors 112 are electrical interface locations that are positioned to receive electrical interface connections that had been connected to the existing electronic device being retrofitted. The three (3) AC power connectors 112 are provided to connect to the three electrical interface connections that exchange three-phase electrical power with the circuit board 104. The two (2) DC power connectors are provided to connect to the positive (+) and negative (-) DC power connections of the AC-to-AC conversion circuit contained on the circuit board 104.

The illustrated circuit board 104 in an example includes electronic components including high power electrical switching devices such as Insulated Gate Bipolar Transistor (IGBT) electrical power switching devices. The circuit board 104 in this example includes connections to an array of large capacitors 120 that are mounted in proximity to the circuit board 104 and within the enclosure formed by the cage frame 108 and base frame 102.

The power electronic device within a protective cooling enclosure 100 further depicts a fan support bracket 106 located within the cage frame 108. The depicted fan support bracket 106 has a number of fans 110 mounted thereto. As shown, the fan support bracket 106 and the fans 110 attached thereto are physically protected by the cage frame 108. It has been observed that cooling of the large capacity capacitors is important to the reliability and operation of the power electronic device within a protective cooling enclosure 100. In the illustrated example, the fans 110 circulate air over the capacitors 120 in order to cool the capacitors to improve cooling of the capacitors 120. The fans 110 in some examples are further are able to improve air circulation and thus cooling over the circuit board 104.

The base frame 102 in the illustrated example has the cage frame 108 attached thereto to provide physical protection for components mounted within the cage frame 108. As noted above, the cage frame 108 defines a number of top openings 130, long side openings 134 and short side openings 136 to facilitate air flow and cooling of components within the cage frame 108. Although the cage frame 108 has openings that allow air and in some instances service access into the interior of the cage frame 108, the cage frame 108 provides physical protections against impacts and other damage due to movement in the restrictive space of the cabinet in which the power electronic device within a protective cooling enclosure 100 is mounted, during movement of the power electronic device in a protective cooling enclosure 100 in general, or combinations of these. The openings, including the top openings 130 long side openings 134, and short side openings 136, as are defined by the cage frame 108, are sized to provide sufficient airflow to support cooling of the components within the cage frame 108 while being sized to reduce the likelihood of impact of objects within the cage frame 108 by objects in the vicinity of the power electronic device within a protective cooling enclosure 100 as it is moved around.

The power electronic device within a protective cooling enclosure 100 is able to be installed in an equipment cabinet that has physically restrictive dimensions that limit physical access to the power electronic device within a protective cooling enclosure 100 during installation or servicing. The circuits in the power electronic device within a protective cooling enclosure 100 in an example process high levels of three-phase AC electrical current and are electrically connected to other systems by several thick and ridged electrical cables. Installation of the power electronic device within a protective cooling enclosure 100 in a cabinet or other location while connected to the several thick and heavy electrical cables can greatly restrict its movement during installation and servicing which increases the likelihood of impact with other components and damaging unprotected components mounted within the power electronic device within a protective cooling enclosure 100.

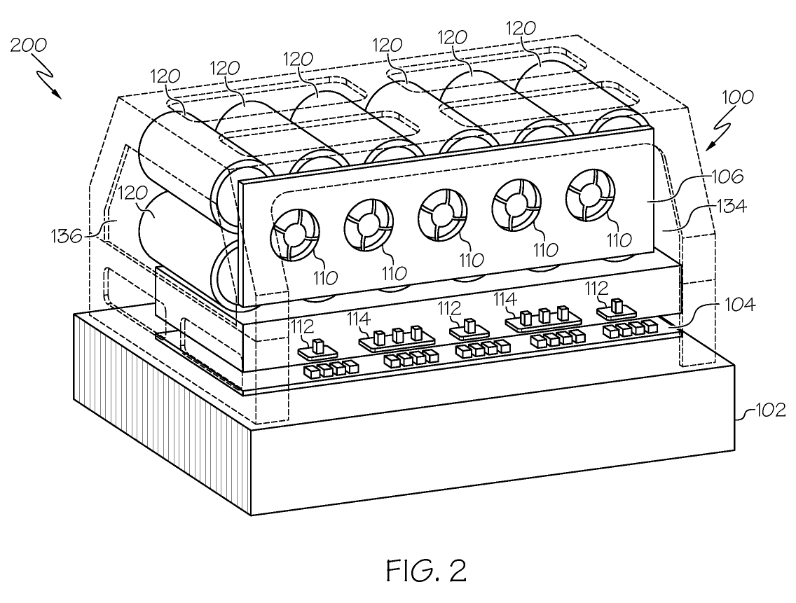

FIG. 2 depicts an electronic device detailed view 200 of the power electronic device within a protective cooling enclosure 100 depicted in FIG. 1, according to an example. With reference to the power electronic device within a protective cooling enclosure 100 described above, the electronic device detailed view 200 depicts the base frame 102, circuit board 104, fan support bracket 106 and its attached fans 110. An outline of an installed cage frame 108 is also depicted for reference.

The electronic device detailed view 200 illustrates the relationship between the fans 110 and capacitors 120 and how those fans 110 improves air circulation around the capacitors. The illustrated relationship between the fans 110 and the circuit board 104 further indicates how the overall airflow through the power electronic device within a protective cooling enclosure 100 facilitates cooling of the circuits on the circuit board 104.

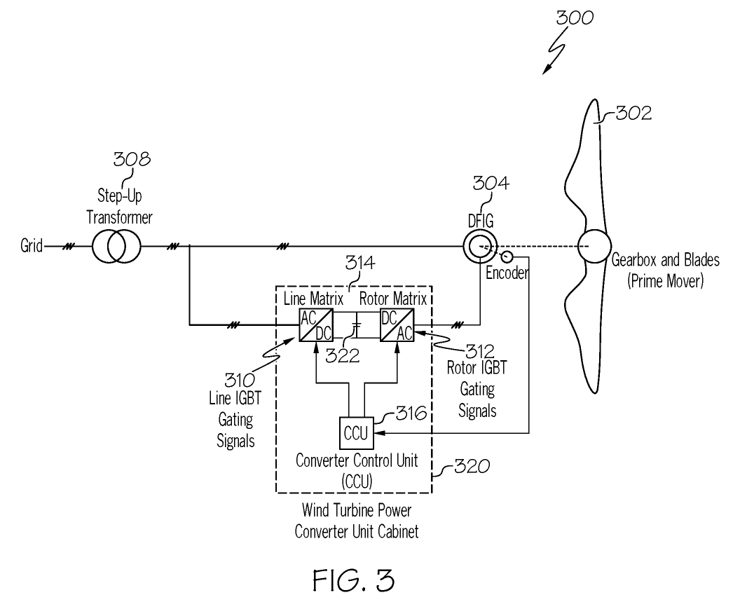

FIG. 3 depicts a wind turbine with an electronic circuit 300 including the power electronic device depicted in FIG. 1, according to an example. The wind turbine with an electronic circuit 300 depicts a wind turbine blade assembly 302 that drives a three-phase power generator 304, which in an example is a Doubly Fed Induction Generator (DFIG). The three-phase power generator 304 provides power to a high voltage three-phase electrical power converter 320.

The high voltage three-phase electrical power converter 320 operates to convert the variable frequency and voltage of three-phase electrical power generated by the wind turbine three-phase power generator 304. The high voltage three-phase electrical power converter 320 has a rotor matrix 312 that in an example consists of a number of IGBT devices arranged in a bridge to convert the three-phase electrical power to a DC power output that is provided to a DC power connection 314. The DC power output carried by the DC power connection 314 is filtered by filter capacitors 322 that form a direct current filtering circuit.

The DC power connection 314 provides DC power to a DC input of a line matrix 310 that that contains another set of IGBT devices that are arranged in a matrix to create a three-phase AC power output from the DC power received via the DC power connection 314. The three-phase AC power produced by the line matrix 310 is connected to a step-up transformer 308 to provide that AC power output to consumers of that AC power. at a constant frequency that is synchronized to an output power grid.

In an example the line matrix 310 and the rotor matrix 312 are each an example of the above described power electronic device within a protective cooling enclosure 100. The filter capacitors 322 correspond to the capacitors 120 described above with regards to the power electronic device within a protective cooling enclosure 100, where the line matrix 310 and the rotor matrix 312 each have these capacitors 120 contained internally in their protective enclosures as described above.

The operation of the high voltage three-phase electrical power converter 320 is controlled by a controller 316. The controller 316 monitors the speed of the three-phase power generator 304 to determine the frequency of its AC output, controls the operation of the rotor matrix 312 and the line matrix 310 in order to most efficiently convert the input AC power to the AC power output to be delivered to the step-up transformer 308.

Because the rotational speed of the wind turbine blade assembly 302 varies due to varying wind speed, the three-phase AC power produced by the three-phase power generator 304 has varying frequency. The operation of high voltage three-phase electrical power converter 320 converts that varying frequency three-phase AC power to a three-phase AC power putout that has the proper voltage, frequency, and phase to property drive the step-up transformer 308 to allow that three-phase AC power to be delivered to consumers.

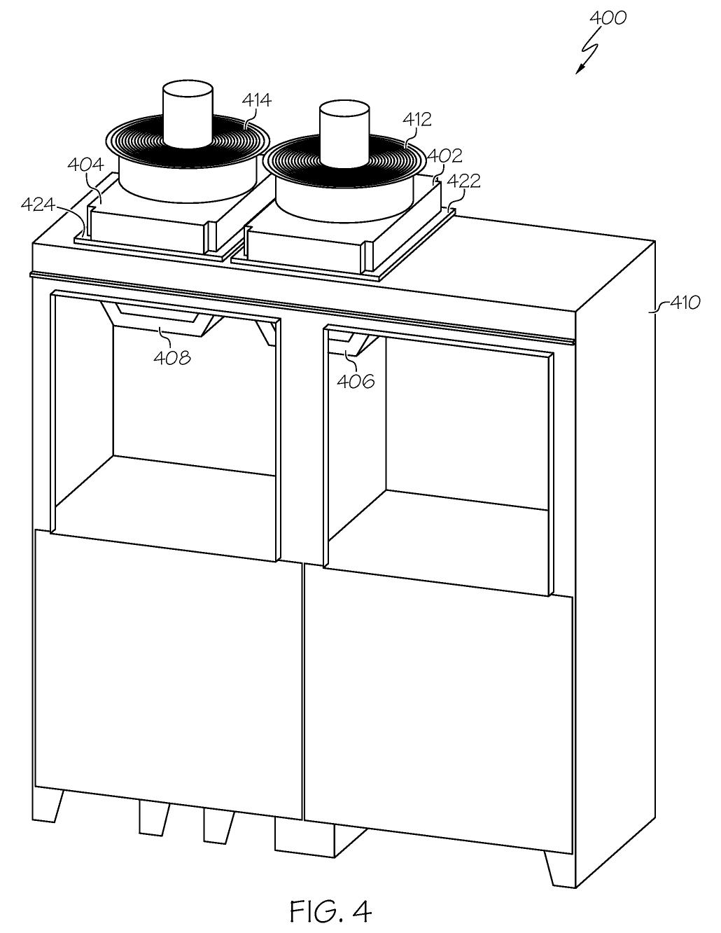

FIG. 4 depicts a power electronics device installation 400 including a power electronic device within a protective cooling enclosure 100 as depicted in FIG. 1, according to an example. The power electronics device installation 400 depicts a cabinet 410 with two (2) power electronic devices within a protective cooling enclosure 100, a first power electronic device within a protective cooling enclosure 402 and a second power electronic device within a protective cooling enclosure 404, that are mounted at openings cut into the top of the cabinet 410. With reference to the wind turbine with an electronic circuit 300, one of these two (2) power electronic device within a protective cooling enclosure 100 corresponds to the rotor matrix 312 and the other corresponds to the line matrix 310. The electrical connection of these two (2) power electronic devices within a protective cooling enclosure 100 is described above with regards to the wind turbine with an electronic circuit 300.

The first power electronic device within a protective cooling enclosure 402 and the second power electronic device within a protective cooling enclosure 404 are mounted in an upside down position relative to the depiction of the power electronic device within a protective cooling enclosure 100 described above. The illustrated first power electronic device within a protective cooling enclosure 402 is shown to have a first base frame 422 that protrudes above the top of the cabinet 410 and a first cage frame 406 that protrudes into the cabinet 410. The second power electronic device within a protective cooling enclosure 402 similarly has a second base frame 424 that protrudes above the top of the cabinet 410 and a second cage frame 408 that protrudes into the cabinet. The first base frame 422 and the second base frame 424 each has a heat sink that is cooled by a first base fan 412 and a second base fan 414, respectively.

As shown for the power electronic device within a protective cooling enclosure 100, the AC power connectors 112 and the DC power connectors 114 of the circuit board 104 in the illustration of the power electronics device installation 400, are located within the close confines of the cabinet 410. The close confines in which the first power electronic device within a protective cooling enclosure 402 and the second power electronic device within a protective cooling enclosure 404 are mounted further impedes the manipulation of cables when connecting the power connectors of these devices to the wiring inside the cabinet 410. Manipulating the thick and heavy conductors to connect them to, for example, the AC power connectors 112 of the protective cooling enclosures 402, 404, as well as manipulating tools inside of the cabinet 410 to connect those conductors and perform other tasks inside the cabinet in the vicinity of the power electronic device within a protective cooling enclosure 402, 404. The difficulties of working in that confined space increases the likelihood of impacting delicate components in the absence of the protection provided by the cage frame 108 attached to the base frame 102.

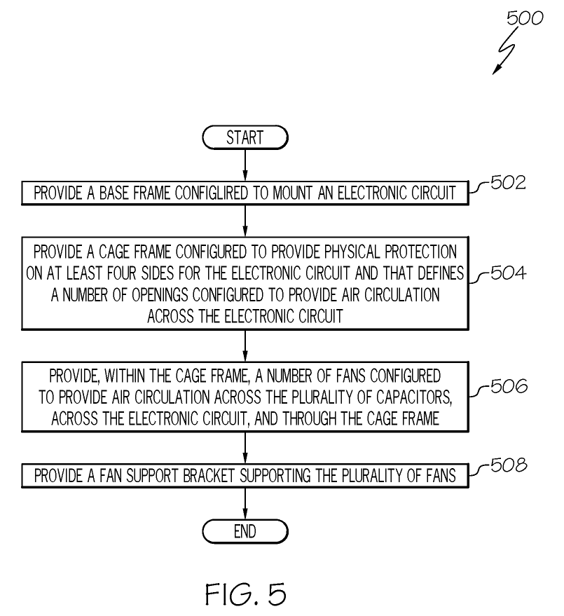

FIG. 5 depicts a method of providing protection and cooling of an electronic circuit 500, according to an example. In one example, the method of providing protection and cooling of an electronic circuit 500 is an example of a method providing protection and cooling to any electronic circuit. In further examples, the method of providing protection and cooling of an electronic circuit 500 is able to be adapted to retrofitting an electronic device, such as retrofitting an installed Alternating Current-to-Alternating Current electric power conversion device.

The method of providing protection and cooling of an electronic circuit 500 provides, at 502. a base frame configured to mount an electronic circuit. An example of such a base frame is discussed above as the base frame 102 of the power electronic device within a protective cooling enclosure 100.

A cage frame configured to provide physical protection on at least four sides for the electronic circuit is provided, at 504. The cage frame defines a number of openings configured to provide air circulation across the electronic circuit. An example of such a cage frame is discussed above as the cage frame 108 of the power electronic device within a protective cooling enclosure 100.

A number of fans configured to provide air circulation across the plurality of capacitors, across the electronic circuit, and through the cage frame, are provided within the cage frame, at 506. In various examples, any number of fans, including one fan, is able to be provided. An example of such fans is described above as the fans 110 of the of the power electronic device within a protective cooling enclosure 100.

A fan support bracket supporting the plurality of fans is provided, at 508. In various examples such a fan support bracket is able to include multiple support brackets to support multiple fans that are provided as described above. An example of such a bracket is described above as the fan support bracket 106 of the of the power electronic device within a protective cooling enclosure 100.

Non-Limiting Examples: Although specific embodiments of the subject matter have been disclosed, those having ordinary skill in the art will understand that changes can be made to the specific embodiments without departing from the spirit and scope of the disclosed subject matter. The scope of the disclosure is not to be restricted, therefore, to the specific embodiments, and it is intended that the appended claims cover any and all such applications, modifications, and embodiments within the scope of the present disclosure.

What is claimed is:

1. A protective enclosure, comprising:
a base frame;
an electronic circuit;
a cage frame depending from the base frame, the cage frame:
configured to provide physical protection on at least four sides for the electronic circuit; and
defining a plurality of openings configured to provide air circulation across the electronic circuit; and
at least one fan disposed within the cage frame and configured to at least partially drive the air circulation.

2. The protective enclosure of claim 1, wherein the electronic circuit comprises an electric power conversion module and is configured to handle at least one (1) Megawatt.

3. The protective enclosure of claim 1, further comprising a fan support bracket supporting a plurality of fans configured to provide air circulation across the electronic circuit and through the cage frame.

4. The protective enclosure of claim 1, wherein the electronic device enclosure is configured as a retrofitting replacement for an existing electronics device.

5. The protective enclosure of claim 4, wherein the base frame is configured to be mounted at an existing physical interface for the existing electronics device.

6. The protective enclosure of claim 5, wherein the electronics circuit comprises electrical interface locations positioned to receive electrical interface connections connecting to the existing electronics device.

7. The protective enclosure of claim 1, wherein the electronic circuit comprises at least one capacitor, and wherein the at least one fan is configured to provide air circulation across the at least one capacitor.

8. The protective enclosure of claim 7, wherein the electronic circuit comprises a plurality of capacitors.

9. The protective enclosure of claim 8, further comprising a plurality of fans configured to provide air circulation across the plurality of capacitors, across the electronic circuit, and through the cage frame.

10. The protective enclosure of claim 9, further comprising a fan support bracket supporting the plurality of fans.

11. The protective enclosure of claim 10, wherein the electronic circuit comprises an Alternating Current-to-Alternating Current conversion circuit, the Alternating Current-to-Alternating Current conversion circuit comprising Insulated Gate Bipolar Transistor switching devices, and wherein the Alternating Current-to-Alternating Current conversion circuit comprises a Direct Current filtering circuit comprising the plurality of capacitors.

12. A method of retrofitting an installed Alternating Current-to-Alternating Current electric power conversion device, the method comprising:
providing a base frame;
providing an electronic circuit comprising a compatible circuit suitable to replace an Alternating Current-to-Alternating Current conversion circuit within the installed Alternating Current-to-Alternating Current conversion device;
providing a cage frame depending from the base frame, the cage frame:
configured to provide physical protection on at least four sides for the electronic circuit; and
defining a plurality of openings configured to provide air circulation across the electronic circuit; and
providing at least one fan disposed within the cage frame and configured to at least partially drive the air circulation.

13. The method of claim 12, wherein the electronic circuit comprises an electric power conversion module and is configured to handle at least one (1) Megawatt.

14. The method of claim 12,
wherein the base frame is configured to be mounted at an existing physical interface for the Alternating Current-to-Alternating Current conversion device; and
wherein the electronic circuit comprises electrical interface locations positioned to receive electrical interface connections connecting to the Alternating Current-to-Alternating Current conversion circuit within the Alternating Current-to-Alternating Current conversion device.

15. A method of providing protection and cooling of an electronic circuit, the method comprising:
providing a base frame;
providing an electronic circuit;
providing a cage frame depending from the base frame, the cage frame:
configured to provide physical protection on at least four sides for the electronic circuit; and
defining a plurality of openings configured to provide air circulation across the electronic circuit; and
providing at least one fan disposed within the cage frame and configured to at least partially drive the air circulation.

16. The method of claim 15, further comprising providing a fan support bracket supporting a plurality of fans configured to provide air circulation across the electronic circuit and through the cage frame.

17. The method of claim 15, wherein the electronic circuit comprises a plurality of capacitors, and wherein the method further comprising providing a plurality of fans configured to provide air circulation across the plurality of capacitors, across the electronic circuit, and through the cage frame.

18. The method of claim 17, further comprising providing a fan support bracket supporting the plurality of fans.

19. The method of claim 18, wherein the electronic circuit comprises an Alternating Current-to-Alternating Current conversion circuit, the Alternating Current-to-Alternating Current conversion circuit comprising Insulated Gate Bipolar Transistor switching devices, and wherein the Alternating Current-to-Alternating Current conversion circuit comprises a Direct Current filtering circuit comprising the plurality of capacitors.

20. The method of claim 19,
wherein the method is performed as part of a retrofitting replacement of an existing electronics device;
wherein the base frame is configured to be mounted at an existing physical interface for the existing electronics device; and
wherein the electronic circuit comprises electrical interface locations positioned to receive electrical interface connections connecting to the existing electronics device.
